(19) United States
(12) Patent Application Publication
(10) Pub. No.: US 2016/0012882 A1
(43) Pub. Date: Jan. 14, 2016

(54) Flux Latching Superconducting Memory

(71) Applicant: Andrew L. Bleloch, Redwood City, CA (US)

(72) Inventor: Andrew L. Bleloch, Redwood City, CA (US)

(73) Assignee: ColdLogix, Inc., San Jose, CA (US)

(21) Appl. No.: 14/769,655

(22) PCT Filed: Mar. 14, 2014
(86) PCT No.: PCT/US14/29700

§ 371 Date: Aug. 21, 2015

Related U.S. Application Data
(60) Provisional application No. 61/785,732, filed on Mar. 14, 2013.

(51) Int. Cl. G11C 11/44

(52) U.S. Cl. CPC G11C 11/44

(57) ABSTRACT

One aspect of the present invention is a cryogenic memory cell to be used in a cryogenic memory system. The cell includes a composite Josephson Junction herein called a flux latching junction. The flux latching junction stores a binary value by virtue of a part of that junction being maintained in a normal or a superconducting state. The system further includes a write line that by the action of a magnetic field, switches the state of the flux latching junction between the two possible binary alternatives. The system also includes a means to sense the state of the flux latching junction using a SQUID or a single Josephson Junction.

### TECHNICAL FIELD

This invention is in the field of superconducting digital electronics and is applicable generally in that field. Examples of devices that would benefit are superconducting classical digital logic circuits including microprocessors, superconducting quantum computing and superconducting digital signal processing. In short, anywhere that is likely to require a cryogenic memory.

### BACKGROUND ART

Superconducting digital electronics has great promise for computing and communications because it is capable of higher speeds than CMOS together with significantly lower total power consumption (i.e. including the cooling power). However, much digital electronics and certainly computing requires memory with a high device density whilst being comparably fast and low power. There are three main classes of cryogenic memory devices in superconducting electronics generally discussed in the research literature as Josephson memory[1], Hybrid cryogenic CMOS memory[2] and JMRAM (Josephson Magnetic Random Access Memory)[3]. At the time of writing, Hybrid cryogenic CMOS memory is the only solution demonstrated to operate at the modest scale of 64 kbit[2]. Josephson memory has been demonstrated with much smaller numbers of bits and a functional Cryogenic MRAM chip has yet to be demonstrated in the research literature.

### DISCLOSURE OF INVENTION

### Technical Problem

The technical disadvantages and hurdles with the three main classes of cryogenic memory mentioned and referenced above in Background Art are as follows:

Josephson memory uses the presence or absence of a quantum of magnetic flux (or fluxon) in a superconducting loop to represent the binary data (for example no fluxon could be 0 and fluxon would then be 1). The loop storing this fluxon must be large enough so that the magnetic field remains below that required to drive the Josephson Junction in the loop to its normal state. This size is determined by the, so-called, Josephson Penetration Depth of the junction materials. In practice, this is several microns in technologies currently implemented. This size limit is likely (the likelihood depends on the detailed choice of materials used) to be more restrictive than the size limit imposed by the need for large inductances. It is unlikely (and generally accepted in the community) therefore that Josephson memory will not scale down to dimensions that are required to enable widespread application of superconducting computing.

Hybrid Cryogenic CMOS memory has the advantage of inheriting the technological developments associated with CMOS. Device density is not a problem. However, it has both the speed and power consumption disadvantages of CMOS and, whilst it is a good interim solution, it will also restrict the widespread application of super-conducting computing.

JMRAM has yet to be demonstrated and therefore cannot be properly assessed as to its utility but it is likely to be comparatively slow and power intensive to write and the manufacture process is likely to be comparatively complex.

This patent presents a technology for making high density, low power and cheaply fabricated superconducting memory that is required to enable widespread adoption of superconducting digital electronics in computing and signal processing.

### Technical Solution

One embodiment of the idea that helps to explain the operation would be a super-conducting wire with a sheath of another superconductor with a significantly lower critical field, Hc. As the current through the wire increases, first the low Hc sheath would allow flux penetration, thus changing the flux distribution around the wire. If the current is then reduced, the sheath would remain normal thus retaining a memory of the high current event. To restore the sheath to its superconducting state, the current is reduced to below a lower threshold. This would also work if the sheath were rolled up into a parallel wire in contact with the central wire but now to one side. In this case, the change in field distribution would be easier to detect because it would be as-symmetric. The transition from superconducting to normal and back can also be achieved by the magnetic field of an additional wire, a ‘write line’, running parallel to but separated from the central wire (rather than by changing the current in the central superconductor). To drive the low Hc material normal, the write line would need to produce a field greater the low Hc and to return it to its superconducting state the write line would need to cancel the field of the central conductor leaving no flux in the low Hc wire for a short time.

A preferred embodiment that retains the central idea of two different critical current superconducting materials in close contact is a single entity, which we call a latch junction, consisting of two parts with differing critical currents. In a simple case this could be part metal part Josephson junction or a composite junction with two junctions areas with different critical currents in two spatially separated parts that are touching or very close. (The composite junction should not be a SQUID with a large separation of the junctions—large in this context is measured with respect to the relevant penetration depths, London or Josephson depending on the material) The fundamental principle on which this device works is by moving flux around but not necessarily in entire units of a fluxon and, once the write cycle is complete, not necessarily changing the total flux present. In other words, changing the field locally but not the necessarily the total flux.

This embodiment of the device works as follows: A constant bias current flows through the latch junction that does not produce a field that exceeds Hc at the outer edge of the low Ic portion. The latch will then remain in this state—call it 1. If the current is increased to exceed the Ic of this portion but not to exceed the Ic of the high Ic part, then the field will penetrate the junction and remain in this new state (say 0) until either the current is reduced or the field is reduced in the normal part. This hysteresis is what stores the information. It is also possible instead of having to vary the bias current to write a 1 or 0, to use an adjacent write line. This would provide a magnetic pulse that would either drive the low Ic part normal, if the magnetic field were in the same direction as the field produced by the bias current or restore the superconducting current if the magnetic field pulse cancels the field or sufficient part of the field of the bias current. A pulse in the write line in one direction would then store a 1 and a pulse in the other direction would store a 0.

The device still requires a means to sense the change in the field as flux penetrates the low Hc portion or is excluded. In one embodiment, this is a small SQUID close to the latch whose voltage will change depending on the field distribution. If the low Hc part of the latch junction has a high aspect ratio, then the direction of the magnetic field close to this low Hc part will rotate by a large angle (possibly approaching a right angle) depending on whether this part is superconducting or not (expelling the flux or allowing it to penetrate). This effect can be exploited in the flux sensing SQUID by aligning the loop so that it is close to perpendicular to one or other of these orientations. In another embodiment the field change or readout sensor is a single Josephson junction configured and positioned so that its critical current depends on the magnitude of the magnetic field. Additionally, by making this single junction not highly rotationally symmetric (eg. not round or square but elliptical or rectangular), with its long axis roughly parallel with the long direction of the low Hc part of the flux latch, the field direction change referred to earlier in this paragraph will have a larger effect on the critical current of this single junction.

In a related embodiment, the latch junction consists of a stack of junctions, one atop the other, thus creating a larger field change that is easier to sense. There is also considerable scope to tune the properties of the latch junction by varying the geometry such as; making structures close to the dimension of the London penetration length and/or making large aspect ratio structures that, again will enhance the change in the flux to be detected. Indeed, the latch junction may be made purely by using geometry. For example if the two parts are respectively square and rectangular with a large aspect ratio and the rectangular part had a small dimension that was comparable to or smaller than the relevant penetration depth, then the geometry would cause the rectangular part to have a lower effective Hc.

### Advantageous Effects

The flux latching superconducting memory elements summarized in the previous section have the following attributes:

They are limited neither to high nor to low magnetic fields unlike existing Josephson memory because the storage mechanism is not flux quantization but whether the low Hc half of the latch junction is in the normal or superconducting state. A combination of field strength and junction materials properties may be chosen to optimize speed and energy consumption rather than be constrained to a narrow range of values.

All the fabrication steps required for the device are a routine part of super-conducting logic fabrication and so no new materials or procedures are required.

Since the inductance and junction critical current are not linked by the need to have a single quantum of flux, the device can be scaled down to sizes limited by the London penetration depth. In other words, a single memory bit cell size less than a cubic micron in a Niobium based technology. Other material systems may allow this to be reduced further.

The power consumption of a well designed cryogenic memory system based on either conventional Josephson memory or the flux latching memory presented here is likely to be dominated by the power required for addressing and access rather than the energy consumption of the individual bit cells. However, it can at least be stated that the energy consumed in the latch junction will be much less than the energy consumed by a Rapid Single Flux Quantum (RSFQ) pulse since the junction is in effect shorted by a superconductor and so no voltage will develop across the switching part of the latch junction.

### DESCRIPTION OF DRAWINGS

FIG. 1. A perspective drawing of a single latching flux junction showing the write line and the lower half of the sensing SQUID. (The top half has been omitted from the drawing for clarity)

### BEST MODE

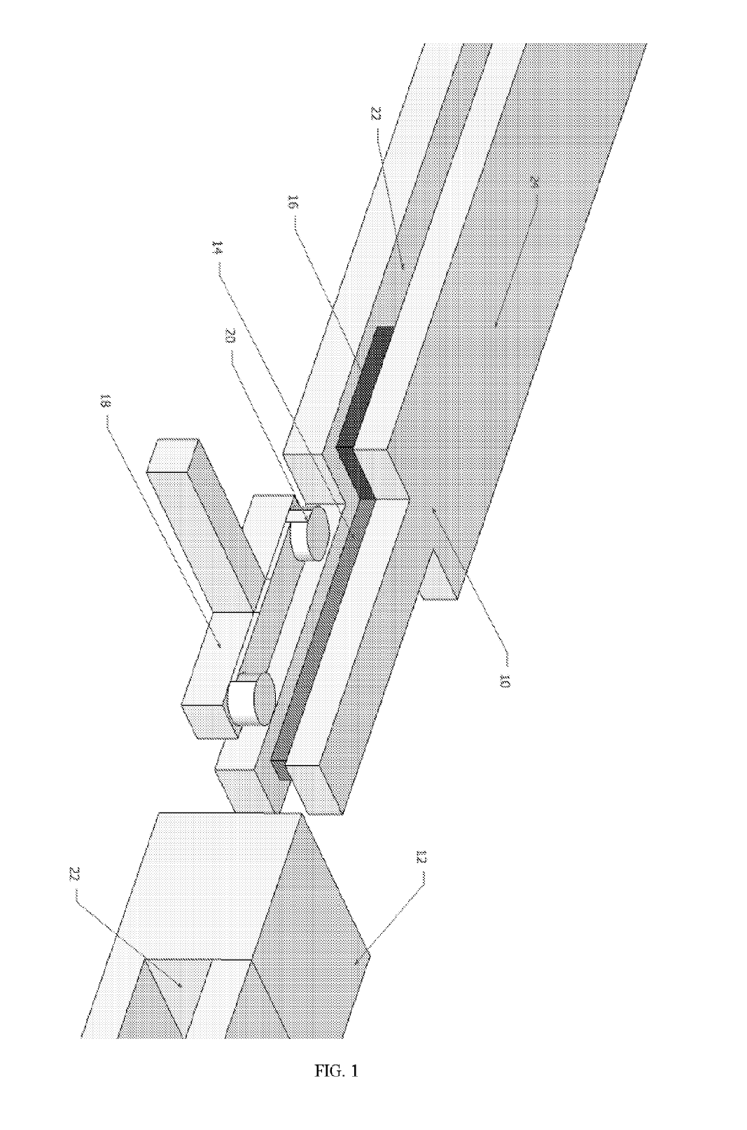

Each memory cell consists of a flux latching junction 10,14 and 16, a write line, 12, and a read sensor, 18, 20, an embodiment of which is shown in FIG. 1. Not shown is an insulator layer that would fill in the gaps between conductors indicated at places 22. The device shown does not include the addressing or arrangement of the cells with respect to one another but it can be seen that it only requires two niobium layers and one junction layer to fabricate. Additional layers will be required to embed the cells in a fully functionary memory chip or device.

In the embodiment illustrated in FIG. 1, all the traces are fabricated from Niobium metal deposited so that it has a superconducting transition temperature close to the bulk value around 9K. The thickness of the traces may be from around 80 nm to a few hundred nm with around 100 nm to 300 nm being the preferred thickness. The insulator thickness may be from 50 nm to a few hundred nm with around 100 nm to 150 nm being the preferred thickness. There are 4 junction regions in FIG. 1: the two SQUID sensor junctions one of which is labeled 20 and the high Hc 16 and low Hc regions of the flux latching junction. The SQUID junctions are standard undamped junctions as fabricated by all superconducting electronic foundries. Note that the upper T shaped connection to the SQUID junctions (which would be a mirror of the lower connection labeled 18 has been omitted for clarity but would be fabricated in the same layer as the upper superconducting layer of the flux latching junction. The high Hc part of the flux latching junction may be a niobium via or it may be the same junction material used in the SQUID junctions if the geometry is carefully chosen so that the low Hc component, using the same material, indeed manifests a lower Hc by virtue of that geometry (i.e. it must be sufficiently narrow and long). As long as the Hc difference is obtained the two parts 14 and 16 may be selected from a wide range of materials including superconductors, normal metals and insulators and geometrically defined weak links. In this particular embodiment, the high Hc part is fabricated as a niobium via. The low Hc part of the flux latching junction, 14, is fabricated with the same junction material as all the junctions in that layer of the wafer.

The lateral dimensions of the device can be chosen over a wide range. The trace widths of the Flux latching junction can be from around 100 nm up to several microns with around 2 microns being the trace width selected in this embodiment. The write line must wide enough to be capable of producing a magnetic field in the low Hc part of the flux latching junction that cancels the field produced when all the bias current is flowing through the high Hc part of the flux latching junction. That field is a function of the bias current indicated by label 24 chosen for the device. That current is chosen to be as low as possible consistent with maintaining the low Hc part of the junction in the latched normal state robustly against thermal noise. A good rule of thumb is around 50 microamps above the threshold required to just maintain the latched state. The lateral sizes of the flux latching junction always have a wide latitude for selection from microns down to the minimum trace widths of around the penetration dept of 8 onm but in this case the high Hc part is a few hundred nm square and the low Hc part is about 500 nm wide and 1 micron long. These dimensions were selected in this case largely because of the constraints of the lithography used in the fabrication.

The range of lateral dimensions can be stretched considerably if a lower super-conducting transition temperature is acceptable or a lower critical current. Dimensions of traces smaller than the London penetration depth can be explored. Also material systems can be selected which have a smaller London penetration depth.

The actual fabrication steps are the same as those practiced in superconducting wafer foundries such as Hypres, Inc and MIT, Lincoln Labs and consist of a series of depositions of metal or insulator interspersed with lithographic patterning of those layers to build up the three layer cell element shown in FIG. 1. It should be noted that the upper and lower layers consist of niobium traces only whereas the middle layer is a combination of niobium vias, junction material and insulator

### REFERENCES

[1] Suzuki, H.; Fujimaki, N.; Tamura, H.; Imamura, T.; Hasuo, S., “A 4K Josephson memory,” Magnetics, IEEE Transactions on, vol. 25, no. 2, pp. 783,788, March 1989
[2] Van Duzer, T. Lizhen Zheng; Whiteley, S. R.; Kim, H.; Jaewoo Kim; Xiaofan
[3] Meng; Ortlepp, T. “64-kb Hybrid Josephson-CMOS 4 Kelvin RAM With 400 ps Access Time and 12 mW Read Power,” Applied Superconductivity, IEEE Transactions on, vol. 23, no. 3, pp. 1700504,1700504, June 2013
[4] (WO2013180946) JOSEPHSON MAGNETIC MEMORY CELL SYSTEM, PCT APPLICATION

1.-7. (canceled)

8. A cryogenic memory cell comprising a composite Josephson junction, said cell storing a binary state having a value of 0 or 1, said value determined by whether a latching portion of the Josephson junction is in a normal state or in a superconducting state.

9. The cryogenic memory cell of claim 8, wherein the latching portion is a flux latching junction.

10. The cryogenic memory cell of claim 8, further comprising a sensing means magnetically coupled to the latching portion, said sensing means adapted to sense the value of the binary state.

11. The cryogenic memory cell of claim 8, wherein the sensing means comprises a SQUID (Superconducting QUantum Interference Device).

12. The cryogenic memory cell of claim 8, wherein the sensing means comprises a single Josephson junction.

13. The cryogenic memory cell of claim 8, further comprising a write line magnetically coupled to the composite Josephson junction, said write line adapted to selectively change the state of the latching portion from normal to superconducting, and from superconducting to normally conducting.

14. The cryogenic memory cell of claim 13, wherein the selective change is performed magnetically.

15. A memory system comprising a plurality of stacked cryogenic memory cells as recited in claim 8, with each cell storing a single binary bit.
